(19) United States
(12) Patent Application Publication
(10) Pub. No.: US 2026/0007028 A1
(43) Pub. Date: Jan. 1, 2026

(54) Display Substrate and Display Device

(71) Applicants: HEFEI BOE JOINT TECHNOLOGY CO., LTD., Hefei, Anhui (CN); BOE TECHNOLOGY GROUP CO., LTD., Chaoyang District, Beijing (CN); BEIJING BOE TECHNOLOGY DEVELOPMENT CO., LTD., Beijing (CN)

(72) Inventor: Yangkun Jing, Beijing (CN)

(21) Appl. No.: 18/711,944

(22) PCT Filed: May 22, 2023
(86) PCT No.: PCT/CN2023/095542

§ 371 Date: May 21, 2024

(51) Int. Cl. H10K 59/35; H10K 59/122

(52) U.S. Cl. CPC H10K 59/353; H10K 59/122; H10K 59/352

(57) ABSTRACT

The present disclosure provides a display substrate and a display device. The display substrate includes: a base substrate; and a plurality of sub-pixel groups on the base substrate, wherein sub-pixels in each sub-pixel group have a same light-emitting color, and sub-pixel groups with different colors are separated by a first bank layer, wherein: the each sub-pixel group includes a plurality of sub-pixels, wherein adjacent sub-pixels are separated by a second bank layer, a height of the second bank layer is less than a height of the first bank layer, the second bank layer is adjacent to the first bank layer, and in the each sub-pixel group, an extension line of a midpoint of the second bank layer between two adjacent sub-pixels in a first direction is not coincident with at least one of extension lines of respective midpoints of the two adjacent sub-pixels in the first direction.

### CROSS-REFERENCE TO RELATED APPLICATION

This application is the United States national phase of International Patent Application No. PCT/CN2023/095542 filed May 22, 2023, the disclosure of which is hereby incorporated by reference in its entirety.

### BACKGROUND OF THE INVENTION

### Field of the Invention

The present disclosure relates to a display substrate and a display device.

### Description of Related Art

In the related art, a pixel structure using high-resolution inkjet printing technology can improve uniformity of film formation in a pixel of a high-resolution printing product. For a pixel bank structure, after ink is printed, the ink between sub-pixels of the same color in each column is separated from each other; and a the line bank structure, after ink is printed, the ink between sub-pixels of the same color in each column is circulated with each other, so that the ink in each sub-pixel is averaged.

### SUMMARY OF THE INVENTION

According to an aspect of the present disclosure, a display substrate is provided. The display substrate comprises: a base substrate; and a plurality of sub-pixel groups on the base substrate, wherein sub-pixels in each sub-pixel group of the plurality of sub-pixel groups have a same light-emitting color, and sub-pixel groups with different colors are separated by a first bank layer, wherein: the each sub-pixel group comprises a plurality of sub-pixels, wherein adjacent sub-pixels of the plurality of sub-pixels are separated by a second bank layer, a height of the second bank layer in a direction perpendicular to the base substrate is less than a height of the first bank layer in the direction perpendicular to the base substrate, the second bank layer is adjacent to the first bank layer, and in the each sub-pixel group, an extension line of a midpoint of the second bank layer between two adjacent sub-pixels of the plurality of sub-pixels in a first direction is not coincident with at least one of extension lines of respective midpoints of the two adjacent sub-pixels in the first direction.

In some embodiments, a width of at least one sub-pixel of the plurality of sub-pixels in a second direction is greater than a width of the second bank layer in the second direction, wherein the second direction intersects with the first direction.

In some embodiments, the extension line of the midpoint of the second bank layer between the two adjacent sub-pixels of the plurality of sub-pixels in the first direction is between the extension lines of the respective midpoints of the two adjacent sub-pixels in the first direction, wherein the second direction intersects with the first direction.

In some embodiments, the first direction is a column direction of a sub-pixel array comprising the plurality of sub-pixel groups.

In some embodiments, the second direction is a row direction of a sub-pixel array comprising the plurality of sub-pixel groups.

In some embodiments, an extension shape of the first bank layer is a broken line shape or a wavy line shape.

In some embodiments, the display substrate comprises a plurality of first bank layers, wherein extension directions of at least two first bank layers of the plurality of first bank layers are substantially parallel, and lengths of the at least two first bank layers are equal.

In some embodiments, the first bank layer comprises a first line portion and a second line portion wherein the first line portion and the second line portion are alternately distributed and connected as a whole, extension directions of different first line portions in the first bank layer are parallel, and extension directions of different second line portions in the first bank layer are parallel.

In some embodiments, the second line portion extends along the second direction; and the first line portion and the second line portion form a first angle.

In some embodiments, the first angle is not 90 degrees.

In some embodiments, a width of the first line portion in the second direction is equal to a width of the second line portion in the first direction.

In some embodiments, the second bank layer comprises a third line portion and a fourth line portion, wherein the third line portion and the fourth line portion are alternately distributed, and extension directions of different third line portions in the second bank layer are parallel, and extension directions of different fourth line portions in the second bank layer are parallel.

In some embodiments, the fourth line portion extends along the second direction; and the third line portion and the fourth line portion form a second angle.

In some embodiments, the second angle is not 90 degrees.

In some embodiments, a width of the third line portion in the second direction is equal to a width of the fourth line portion in the first direction.

In some embodiments, a width of the first bank layer in a direction perpendicular to an extension direction of the first bank layer is equal to a width of the second bank layer in a direction perpendicular to an extension direction of the second bank layer.

In some embodiments, the height of the first bank layer ranges from 1.2 microns to 1.8 microns; and the height of the second bank layer ranges from 0.5 micron to 1 micron.

In some embodiments, a material of the first bank layer is the same as a material of the second bank layer, and the first bank layer and the second bank layer are connected as a whole.

In some embodiments, the plurality of sub-pixel groups comprise a red sub-pixel group, a blue sub-pixel group and a green sub-pixel group, wherein an area of a red sub-pixel in the red sub-pixel group, an area of a blue sub-pixel in the blue sub-pixel group and an area of a green sub-pixel in the green sub-pixel group are all equal.

In some embodiments, the plurality of sub-pixel groups comprise a red sub-pixel group, a blue sub-pixel group and a green sub-pixel group, wherein an area of a blue sub-pixel in the blue sub-pixel group is greater than an area of a red sub-pixel in the red sub-pixel group, and the area of the blue sub-pixel in the blue sub-pixel group is greater than an area of a green sub-pixel in the green sub-pixel group.

In some embodiments, the second bank layer comprises a third line portion and a fourth line portion adjacent to the third line portion; and the each sub-pixel group comprises at least three sub-pixels, wherein the at least three sub-pixels comprises a first sub-pixel, a second sub-pixel adjacent to the first sub-pixel and a third sub-pixel adjacent to the second sub-pixel, wherein the first sub-pixel and the second sub-pixel are separated by the third line portion, and the second sub-pixel and the third sub-pixel are separated by the fourth line portion.

In some embodiments, a shape of each of the plurality of sub-pixels is a parallelogram shape or an ellipse shape; and the first sub-pixel is in a same sub-pixel row as the second sub-pixel, and the second sub-pixel is in a different sub-pixel row from the third sub-pixel.

In some embodiments, the at least three sub-pixels comprise a plurality of sub-pixel rows, wherein each of the plurality of sub-pixel rows comprises at least two sub-pixels, and in the each sub-pixel group, the at least two sub-pixels in different sub-pixel rows are arranged in a staggered manner.

In some embodiments, a shape of each of the plurality of sub-pixels is a rhombic shape or a triangle shape; and the first sub-pixel is in a different sub-pixel row from the second sub-pixel, the second sub-pixel is in a different sub-pixel row from the third sub-pixel, and a sub-pixel row where the second sub-pixel is located is between a sub-pixel row where the first sub-pixel is located and a sub-pixel row where the third sub-pixel is located.

In some embodiments, a shape of each of the plurality of sub-pixels is a hexagonal shape or a circular shape; in the each sub-pixel group, a center of the first sub-pixel, a center of the second sub-pixel and a center of the third sub-pixel are at different vertices of an equilateral triangle; and the first sub-pixel and the third sub-pixel are separated by another third line portion or another fourth line portion.

According to another aspect of the present disclosure, a display device is provided. The display device comprises the display substrate as described previously.

Other features and advantages of the present disclosure will become explicit from the following detailed description of exemplary embodiments of the present disclosure with reference to the accompanying drawings.

### BRIEF DESCRIPTION OF THE DRAWINGS

The accompanying drawings which constitute a part of this specification, describe the embodiments of the present disclosure, and together with this specification, serve to explain the principles of the present disclosure.

The present disclosure may be more explicitly understood from the following detailed description with reference to the accompanying drawings, in which:

FIG. 1 is a top view showing a display substrate according to an embodiment of the present disclosure;

FIG. 2 is a schematic cross-sectional view showing a structure of a display substrate taken along line A-A′ in FIG. 1 according to an embodiment of the present disclosure;

FIG. 3 is a top view showing a display substrate according to another embodiment of the present disclosure;

FIG. 4 is an enlarged schematic view showing a partial structure of a display substrate according to another embodiment of the present disclosure;

FIG. 5 is a top view showing a display substrate according to another embodiment of the present disclosure;

FIG. 6 is a top view showing a display substrate according to another embodiment of the present disclosure;

FIG. 7 is a top view showing a display substrate according to another embodiment of the present disclosure;

FIG. 8 is a top view showing a display substrate according to another embodiment of the present disclosure;

FIG. 9 is a top view showing a display substrate according to another embodiment of the present disclosure;

FIG. 10 is a top view showing a display substrate according to another embodiment of the present disclosure;

FIG. 11 is a top view showing a display substrate according to another embodiment of the present disclosure;

FIG. 12 is a schematic view showing an elliptical sub-pixel according to an embodiment of the present disclosure;

FIG. 13 is a schematic view showing a hexagonal sub-pixel according to an embodiment of the present disclosure;

FIG. 14A is a schematic view showing calculation of an area of a sub-pixel according to an embodiment of the present disclosure;

FIG. 14B is a schematic view showing calculation of an area of a sub-pixel with long axis connection according to an embodiment of the present disclosure;

FIG. 14C is a schematic view showing calculation of an area of a sub-pixel connected in a staggered manner according to another embodiment of the present disclosure;

FIG. 15 is a schematic view showing arrangement of a sub-pixel according to an embodiment of the present disclosure.

It should be understood that the dimensions of various parts shown in the accompanying drawings are not necessarily drawn according to actual proportional relations. In addition, the same or similar components are denoted by the same or similar reference signs.

### DESCRIPTION OF THE INVENTION

Various exemplary embodiments of the present disclosure will now be described in detail in conjunction with the accompanying drawings. The description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as “comprise”, “include”, or the like means that the element before the word covers the element(s) listed after the word without excluding the possibility of also covering other elements. The terms “up”, “down”, “left”, “right”, or the like are used only to represent a relative positional relationship, and the relative positional relationship may be changed correspondingly if the absolute position of the described object changes.

In the present disclosure, when it is described that a particular device is located between the first device and the second device, there may be an intermediate device between the particular device and the first device or the second device, and alternatively, there may be no intermediate device. When it is described that a particular device is connected to other devices, the particular device may be directly connected to the other devices without an intermediate device, and alternatively, may not be directly connected to the other devices but with an intermediate device.

All the terms (comprising technical and scientific terms) used in the present disclosure have the same meanings as understood by those skilled in the art of the present disclosure unless otherwise defined. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

The inventor of the present disclosure has found that, in the related art, during the process of forming a pixel structure of the display substrate by using high-resolution inkjet printing technology, the high-resolution inkjet printing technology might affect the resolution of the display substrate.

In view of this, an embodiment of the present disclosure provides a display substrate to improve the resolution of the display substrate without affecting the display uniformity of the display substrate.

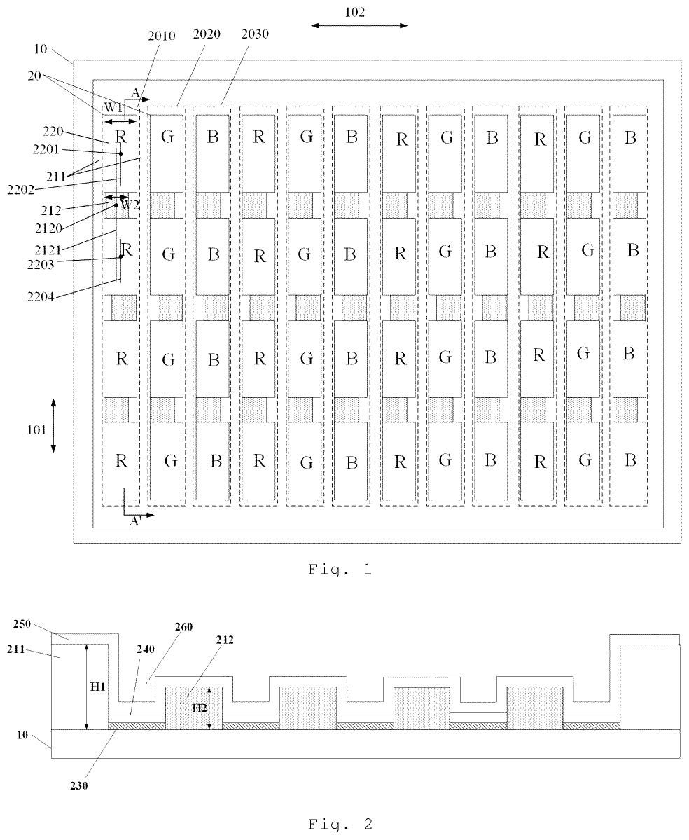

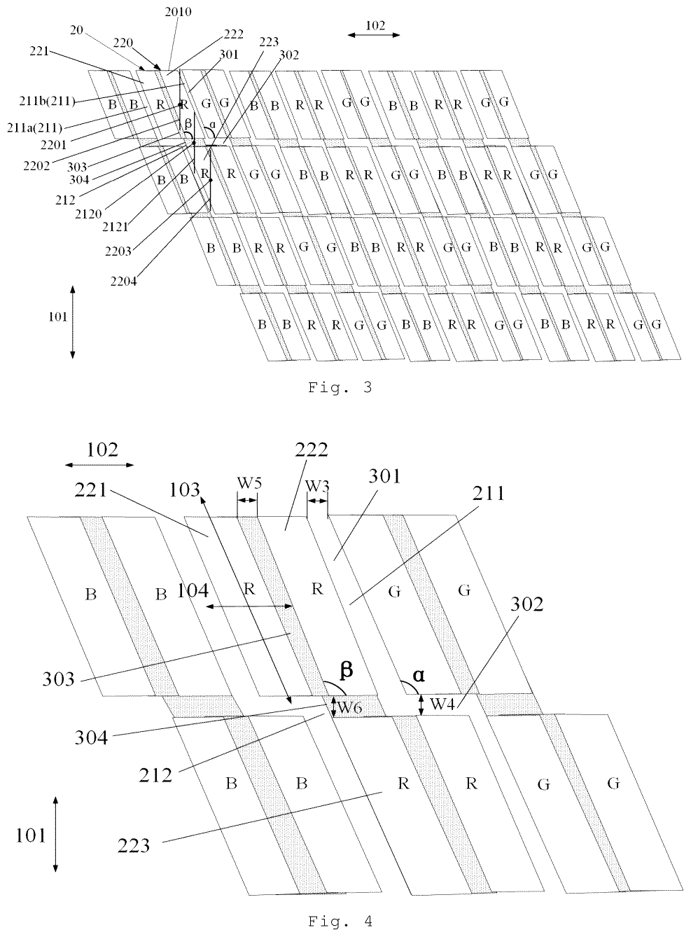

FIG. 1 is a top view showing a display substrate according to an embodiment of the present disclosure. FIG. 2 is a schematic cross-sectional view showing a structure of a display substrate taken along line A-A′ in FIG. 1 according to an embodiment of the present disclosure.

As shown in FIGS. 1 and 2, the display substrate comprises a base substrate 10. For example, the base substrate is a flexible substrate or a rigid substrate.

As shown in FIG. 1, the display substrate further comprises a plurality of sub-pixel groups 20 on the base substrate 10. As shown in FIG. 1, all the sub-pixels in a dashed border form a sub-pixel group. For example, as shown in FIG. 1, a plurality of red sub-pixels R in a same column (for example, a first column) form a sub-pixel group 20, which may be referred to as a first sub-pixel group 2010, a plurality of green sub-pixels G in a same column (for example, a second column) form another sub-pixel group 20, which may be referred to as a second sub-pixel group 2020, and a plurality of blue sub-pixels Bin a same column (for example, a third column) form another sub-pixel group 20, which may be referred to as a third sub-pixel group 2030, and so on. Sub-pixels in each sub-pixel group 20 have a same light-emitting color. For example, as shown in FIG. 1, the light-emitting colors of the sub-pixels in one sub-pixel group (for example, the first sub-pixel group mentioned above) are all red, the light-emitting colors of the sub-pixels in another sub-pixel group (for example, the second sub-pixel group mentioned above) are all green, and the light-emitting colors of the sub-pixels in another sub-pixel group (for example, the third sub-pixel group mentioned above) are all blue. As shown in FIG. 1, sub-pixel groups 20 with different colors are separated by a first bank layer 211.

As shown in FIG. 1, each sub-pixel group comprises a plurality of sub-pixels 220. For example, the first sub-pixel group 2010 comprises a plurality of red sub-pixels R, the second sub-pixel group 2020 comprises a plurality of green sub-pixels G, and the third sub-pixel group 2030 comprises a plurality of blue sub-pixels B. Adjacent sub-pixels of the plurality of sub-pixels are separated by a second bank layer 212. As shown in FIG. 2, a height H2 of the second bank layer 212 in a direction perpendicular to the base substrate 10 is less than a height H1 of the first bank layer 211 in the direction perpendicular to the base substrate 10. For example, the height H1 of the first bank layer 211 ranges from 1.2 microns to 1.8 microns. For example, the height H2 of the second bank layer 212 ranges from 0.5 micron to 1 micron.

In addition, as shown in FIG. 1, the second bank layer 212 is adjacent to the first bank layer 211. In this way, a portion of the second bank layer 212 that retracts along a second direction is replaced by the first bank layer 211.

As shown in FIG. 1, in each sub-pixel group 20, an extension line of a midpoint of the second bank layer between two adjacent sub-pixels of the plurality of sub-pixels in a first direction is not coincident with at least one of extension lines of respective midpoints of the two adjacent sub-pixels in the first direction. For example, an extension line 2121 of a midpoint 2120 of the second bank layer 212 between two adjacent sub-pixels of the plurality of sub-pixels R in the first sub-pixel group 2010 in the first direction 101 is not coincident with an extension line 2202 of a midpoint 2201 of one sub-pixel in the first direction 101, and the extension line 2121 of the midpoint 2120 of the second bank layer 212 in the first direction 101 is not coincident with an extension line 2204 of a midpoint 2203 of another sub-pixel in the first direction 101. Of course, those skilled in the art may understand from the above description that, the extension line 2121 of the midpoint 2120 of the second bank layer 212 in the first direction 101 may not be coincident with one of the extension line 2202 of the midpoint 2201 of the one sub-pixel in the first direction 101 and the extension line 2204 of the midpoint 2203 of the another sub-pixel in the first direction 101.

So far, a display substrate according to an embodiment of the present disclosure is provided. The display substrate comprises: a base substrate; and a plurality of sub-pixel groups on the base substrate, wherein sub-pixels in each sub-pixel group of the plurality of sub-pixel groups have a same light-emitting color, and sub-pixel groups with different colors are separated by a first bank layer, wherein: the each sub-pixel group comprises a plurality of sub-pixels, wherein adjacent sub-pixels of the plurality of sub-pixels are separated by a second bank layer, a height of the second bank layer in a direction perpendicular to the base substrate is less than a height of the first bank layer in the direction perpendicular to the base substrate, and in the each sub-pixel group, an extension line of a midpoint of the second bank layer between two adjacent sub-pixels of the plurality of sub-pixels in a first direction is not coincident with at least one of extension lines of respective midpoints of the two adjacent sub-pixels in the first direction. In this embodiment, in each sub-pixel group, since the extension line of the midpoint of the second bank layer between two adjacent sub-pixels of the plurality of sub-pixels in the first direction is not coincident with at least one of extension lines of respective midpoints of the two adjacent sub-pixels in the first direction, during the process of forming a pixel structure of the display substrate by using inkjet printing technology, ink used can flow into openings of different sub-pixels in the same sub-pixel group as uniformly as possible, and is separated by different first and second bank layers as much as possible, so that different sub-pixels may not affect each other as much as possible, thereby improving the resolution of the display substrate without affecting the uniformity of the display substrate.

In some embodiments, as shown in FIG. 1, in each sub-pixel group 20, a width W1 of at least one sub-pixel of the plurality of sub-pixels in a second direction 102 is greater than a width W2 of the second bank layer 212 in the second direction 102. For example, the width W1 of the sub-pixel R in the first sub-pixel group 2010 is greater than the width W2 of the second bank layer 212. In this way, a portion of the second bank layer that retracts along the first direction is replaced by a portion of the first bank layer adjacent to the second bank layer. Therefore, during the process of forming the pixel structure of the display substrate by using inkjet printing technology, the ink used can flow into the openings of different sub-pixels in the same sub-pixel group as uniformly as possible, and is separated by different first and second bank layers as much as possible, so that different sub-pixels may not affect each other as much as possible, thereby improving the resolution of the display substrate without affecting the uniformity of the display substrate.

As shown in FIG. 1, the second direction 102 intersects with the first direction 101. For example, the second direction 102 is perpendicular to the first direction 101. For example, the first direction 101 is a column direction of a sub-pixel array comprising the plurality of sub-pixel groups, and the second direction 102 is a row direction of a sub-pixel array comprising the plurality of sub-pixel groups.

In some embodiments, as shown in FIG. 2, the display substrate further comprises an electrode layer 230, wherein at least a portion of the electrode layer 230 is exposed by an opening 260 of the sub-pixel. For example, the electrode layer 230 is an anode layer.

In some embodiments, as shown in FIG. 2, the display substrate further comprises a first film layer 240 on the electrode layer 230. For example, the first film layer 240 comprises a hole injection layer, a hole transport layer and a light-emitting layer. For example, the first film layer is a film layer formed by a printing process.

In some embodiments, as shown in FIG. 2, the display substrate further comprises a second film layer 250 covering the first bank layer 211, the second bank layer 212 and the first film layer 240. For example, the second film layer 250 comprises an electron transport layer, an electron injection layer and another electrode layer (for example, a cathode layer). For example, the second film layer is a film layer formed by an evaporation process, so that the second film layer is a film layer formed as a whole surface.

The inventor of the present disclosure has also found that, for the display substrate in the related art, when the pixel structure is manufactured by an inkjet printing process, the sub-pixels may have a low light-emitting uniformity.

In view of this, the embodiment of the present disclosure also provides another display substrate to improve the light-emitting uniformity and pixel opening ratio of the sub-pixels.

FIG. 3 is a top view showing a display substrate according to another embodiment of the present disclosure. FIG. 4 is an enlarged schematic view showing a partial structure of a display substrate according to another embodiment of the present disclosure.

As shown in FIG. 3, the display substrate comprises: a base substrate (not shown in FIG. 3) and a plurality of sub-pixel groups 20 on the base substrate. The base substrate is the same as or similar to the base substrate 10 in FIG. 1. Similar to the display substrate shown in FIG. 1, in the display substrate shown in FIG. 3, sub-pixels in each sub-pixel group 20 have a same light-emitting color, and sub-pixel groups with different colors are separated by a first bank layer 211. Each sub-pixel group 20 comprises a plurality of sub-pixels, wherein adjacent sub-pixels of the plurality of sub-pixels are separated by a second bank layer 212, a height of the second bank layer 212 in a direction perpendicular to the base substrate is less than a height of the first bank layer 211 in the direction perpendicular to the base substrate. In each sub-pixel group, an extension line of a midpoint of the second bank layer between two adjacent sub-pixels of the plurality of sub-pixels in a first direction is not coincident with at least one of extension lines of respective midpoints of the two adjacent sub-pixels in the first direction.

In some embodiments, the extension line of the midpoint of the second bank layer between the two adjacent sub-pixels of the plurality of sub-pixels in the first direction is between the extension lines of the respective midpoints of the two adjacent sub-pixels in the first direction, wherein the second direction intersects with the first direction.

For example, as shown in FIG. 3, taking the first sub-pixel group 2010 comprising a plurality of red sub-pixels R as an example, in the first sub-pixel group 2010, the extension line 2121 of the midpoint 2120 of the second bank layer between two adjacent sub-pixels 222 and 223 (described later) of the plurality of sub-pixels in the first direction 101 is between the extension line 2202 of the midpoint 2201 of one sub-pixel 222 of the two adjacent sub-pixels in the first direction 101 and the extension line 2204 of the midpoint 2203 of the other sub-pixel 223 of the two adjacent sub-pixels in the first direction 101. In this way, during the process of forming the pixel structure by using an inkjet printing process, the ink can be distributed as evenly as possible among the sub-pixels in each sub-pixel group, thereby improving the light-emitting uniformity of the sub-pixels.

As shown in FIG. 3, a shape of each sub-pixel 220 is a parallelogram shape. It is to be noted that, in the description of the embodiment of the present disclosure, the shape of the sub-pixel is a shape of the opening of the sub-pixel. Therefore, in the embodiment, the shape of the opening of each sub-pixel 220 is a parallelogram shape. In other words, a pixel defining pattern of the pixel defining layer is a parallelogram shape. Each sub-pixel group comprises at least three sub-pixels. For example, the at least three sub-pixels comprise a first sub-pixel 221, a second sub-pixel 222 and a third sub-pixel 223. The first sub-pixel 221 is in a same sub-pixel row as the second sub-pixel 222, and the second sub-pixel 222 is in a different sub-pixel row from the third sub-pixel 223. It is to be noted that, each sub-pixel row consists of a row of sub-pixels arranged along the second direction 102 (that is, the row direction). As shown in FIG. 4, each sub-pixel has a long axis direction 103 and a short axis direction 104. The short axis direction 104 is parallel to the second direction 102.

In the embodiment, the arrangement of the above-described sub-pixels is that: in each sub-pixel group, each sub-pixel is designed to be arranged in a staggered manner in the long axis direction and the short axis direction. In this way, it is possible to improve the uniformity of the pixels as much as possible, which is beneficial to improve the light-emitting uniformity and pixel opening ratio of the sub-pixels. The above-described design may also improve the uniformity of forming a film along a long axis direction.

In some embodiments, the at least three sub-pixels in each sub-pixel group comprise a plurality of sub-pixel rows (for example, two or more sub-pixel rows). As shown in FIG. 3, each sub-pixel row comprises at least two sub-pixels. For example, the first sub-pixel row in a first row comprises a first sub-pixel 221 and a second sub-pixel 222. In each sub-pixel group, the at least two sub-pixels in different sub-pixel rows are arranged in a staggered manner. For example, as shown in FIG. 3, the sub-pixel row where the first sub-pixel 221 is located (that is, the first sub-pixel row) and the sub-pixel row where the third sub-pixel 223 is located (which may be referred to as a second sub-pixel row) are arranged in a staggered manner. In this way, the staggered arrangement of the sub-pixels is beneficial to improve the light-emitting uniformity and pixel opening ratio of the sub-pixels.

Of course, those skilled in the art can understand that each sub-pixel row in each sub-pixel group may also comprise one sub-pixel, and different sub-pixel rows in each sub-pixel group are arranged in a staggered manner. For example, as shown in FIG. 15, red sub-pixels R in one sub-pixel group are arranged in a staggered manner, green sub-pixels G in another sub-pixel group are arranged in a staggered manner, and blue sub-pixels B in another sub-pixel group are arranged in a staggered manner. FIG. 15 also shows a data line 1510 for transmitting data (for example, data R of a red sub-pixel, data G of a green sub-pixel or data B of a blue sub-pixel).

As shown in FIG. 3, an extension shape of the first bank layer 211 is a broken line shape or a wavy line shape. In this way, it is possible to improve the light-emitting uniformity without affecting the resolution of the display substrate.

In some embodiments, as shown in FIG. 3, the display substrate comprises a plurality of first bank layers 211. Extension directions of at least two first bank layers (for example, first bank layers 211a and 211b on both sides of the sub-pixel group respectively) of the plurality of first bank layers are substantially parallel, and lengths of the at least two first bank layers are equal. In this way, different sub-pixel groups can be orderly separated, which is beneficial to improve the light-emitting uniformity of the entire display substrate.

In some embodiments, as shown in FIGS. 3 and 4, the first bank layer 211 comprises a first line portion 301 and a second line portion 302. The first line portion 301 and the second line portion 302 are alternately distributed and connected as a whole. Extension directions of different first line portions 301 in the first bank layer 211 are parallel, and extension directions of different second line portions 302 in the first bank layer 211 are parallel. For example, the first bank layer 211 comprises a plurality of first line portions 301 and a plurality of second line portions 302, and in a same first bank layer 211, extension directions of the plurality of first line portions 301 are parallel to each other, and extension directions of the plurality of second line portions 302 are parallel to each other. This is beneficial to improve the light-emitting uniformity of the entire display substrate.

In some embodiments, as shown in FIGS. 3 and 4, extension directions of different first line portions 301 in different first bank layers 211 are parallel, and extension directions of different second line portions 302 in different first bank layers 211 are parallel. This is beneficial to further improve the light-emitting uniformity of the entire display substrate.

In some embodiments, as shown in FIGS. 3 and 4, the second line portion 302 of the first bank layer 211 extends along the second direction 102. The first line portion 301 and the second line portion 302 form a first angle α. In some embodiments, the first angle α is not 90 degrees. For example, the first angle α is an obtuse angle. This is beneficial to allow that each sub-pixel in the sub-pixel group is designed as a parallelogram, and the sub-pixels are arranged in a staggered manner along the long axis direction and the short axis direction, which is beneficial to improve the light-emitting uniformity and pixel opening ratio of the sub-pixels.

In some embodiments, as shown in FIG. 4, a width W3 of the first line portion 301 in the second direction 102 is equal to a width W4 of the second line portion 302 in the first direction 101. In this way, a distance between adjacent sub-pixel groups is equal, so that sub-pixel groups are arranged at equal pitches, thereby improving the light-emitting uniformity of the sub-pixels.

Furthermore, the above-described equal pitch design of the sub-pixel group is also beneficial to improve the uniformity of the ink jet printing process, so that it is beneficial to control a printing frequency of a printer during the inkjet printing process and improve stability and speed of inkjet printing, and it is beneficial to achieve mass production of the inkjet printing products, thereby meeting the requirements of high pixel density products as much as possible. In addition, the above-described equal pitch design of the sub-pixel group may also improve the tolerance of landing error of ink droplets, which is suitable for printing with high PPI and improves the PPI of the display substrate. Here, PPI (Pixels Per Inch), also referred to as a pixel density unit, represents the number of pixels per inch possessed.

Of course, those skilled in the art may understand that, the width W3 of the first line portion 301 in the second direction 102 may not be equal to the width W4 of the second line portion 302 in the first direction 101, so the scope of the present disclosure is not limited thereto.

In some embodiments, as shown in FIGS. 3 and 4, the second bank layer 212 comprises a third line portion 303 and a fourth line portion 304. The third line portion 303 and the fourth line portion 304 are alternately distributed. Extension directions of different third line portions 303 in the second bank layer 212 are parallel, and extension directions of different fourth line portions 304 in the second bank layer 212 are parallel. For example, the second bank layer 212 comprises a plurality of third line portions 303 and a plurality of fourth line portions 304, and in a same first bank layer 211, extension directions of the plurality of first line portions 301 are parallel to each other, and extension directions of the plurality of second line portions 302 are parallel to each other. This is beneficial to improve the light-emitting uniformity and opening ratio of the sub-pixels.

In some embodiments, as shown in FIGS. 3 and 4, extension directions of different third line portions 303 in different second bank layers 212 are parallel, and extension directions of different fourth line portions 304 in different second bank layers 212 are parallel. This is beneficial to further improve the light-emitting uniformity and opening ratio of the sub-pixels.

In some embodiments, as shown in FIGS. 3 and 4, the fourth line portion 304 of the second bank layer 212 extends along the second direction 102. The third line portion 303 and the fourth line portion 304 form a second angle β. In some embodiments, the second angle β is not 90 degrees. For example, the second angle β is an obtuse angle. This is beneficial to allow that each sub-pixel in the sub-pixel group is designed as a parallelogram, and arranged in a staggered manner in the long-axis direction and the short-axis direction, which is beneficial to improve the light-emitting uniformity and pixel opening ratio of the sub-pixels.

In some embodiments, as mentioned above, the shape of each sub-pixel 220 may be a parallelogram shape, and accordingly, the first angle α may be equal to the second angle β.

In some embodiments, as shown in FIG. 4, a width W5 of the third line portion 303 in the second direction 102 is equal to a width W6 of the fourth line portion 304 in the first direction 101. In this way, the distance between sub-pixels is equal, so that the sub-pixels are arranged at equal pitches, thereby improving the light-emitting uniformity of the sub-pixels.

Furthermore, the equal pitch design of the sub-pixels is also beneficial to improve the uniformity in the implementation of the inkjet printing process, so that it is beneficial to control a printing frequency of a printer during the inkjet printing process and improve the stability and speed of inkjet printing, and it is beneficial to achieve mass production of the inkjet printing products, thereby meeting the requirements of high pixel density products as much as possible. In addition, the above-described equal pitch design of the sub-pixel group may also improve the tolerance of landing error of ink droplets, which is suitable for printing with high PPI and improves the PPI of the display substrate.

Of course, those skilled in the art may understand that the width W5 of the third line portion 303 in the second direction 102 may not be equal to the width W6 of the fourth line portion 304 in the first direction 101. For example, the width W5 of the third line portion 303 in the second direction 102 is less than the width W6 of the fourth line portion 304 in the first direction 101. Therefore, the scope of the present disclosure is not limited thereto.

In some embodiments, as shown in FIG. 4, a width (for example, the width W3 and/or W4) of the first bank layer 211 in a direction perpendicular to an extension direction of the first bank layer 211 is equal to a width (for example, the width W5 and/or W6) of the second bank layer 212 in a direction perpendicular to an extension direction of the second bank layer 212. In other words, the width W3 of the first line portion 301, the width W4 of the second line portion 302, the width W5 of the third line portion 303 and the width W6 of the fourth line portion 304 are all equal. In this way, the distance between adjacent sub-pixels in the display substrate is equal, so that the sub-pixels are arranged at equal pitches, which may ensure the same microenvironment on both sides of the pixel at the opening as much as possible, and improve the atmosphere consistency during the implementation of the inkjet printing process, thereby facilitating the uniformity of forming a film and improving the light-emitting uniformity of the sub-pixels of the display substrate.

Moreover, the equal pitch design of each sub-pixel is also beneficial to improve the uniformity during the implementation of the inkjet printing process, so that it is beneficial to control a printing frequency of a printer during the inkjet printing process and improve the stability and speed of inkjet printing, and it is beneficial to achieve mass production of the inkjet printing products, thereby meeting the requirements of high pixel density products as much as possible.

In some embodiments, as shown in FIGS. 3 and 4, the fourth line portion 304 is adjacent to the third line portion 303. That is, the second bank layer 212 comprises a third line portion 303 and a fourth line portion 304 adjacent to the third line portion 303. Each sub-pixel group comprises at least three sub-pixels. The at least three sub-pixels comprise a first sub-pixel 221, a second sub-pixel 222 adjacent to the first sub-pixel 221 and a third sub-pixel 223 adjacent to the second sub-pixel 222. The first sub-pixel 221 and the second sub-pixel 222 are separated by the third line portion 303, and the second sub-pixel 222 and the third sub-pixel 223 are separated by the fourth line portion 304. For example, as shown in FIGS. 3 and 4, the first sub-pixel 221 and the second sub-pixel 222 are arranged along the second direction 102, and the second sub-pixel 222 and the third sub-pixel 223 are arranged along an extension direction of the first line portion 301 of the first bank layer 211.

By way of the arrangement of the above sub-pixels, a connection length of the sub-pixels may be longer and the uniformity of the sub-pixels may be better.

Since the printer may print at a rotation angle and may print at different positions through pixel pattern editing, and since the print heads of the printer are in a multi-column (for example, three-column) parallel array, the corresponding print patterns are also parallel arrays.

In some embodiments, a material of the first bank layer 211 is the same as a material of the second bank layer 212, and the first bank layer 211 and the second bank layer 212 are connected as a whole. In this way, the openings of sub-pixels formed by the first bank layer and the second bank layer can be more clearly distinguished, thereby improving the resolution of the display substrate. In addition, the embodiment also facilitates the manufacture of the first bank layer and the second bank layer, thereby facilitating the manufacture of the display substrate and reducing the manufacturing cost.

In some embodiments, during the process of forming the first bank layer and the second bank layer, exposure and development may be performed by using a halftone mask. Although a height of the first bank layer is different from a height of the second bank layer, during the process of forming the bank layer, the exposure and development process may be completed by using a halftone mask through single exposure and development, so as to form the first bank layer and the second bank layer.

Here, the halftone mask refers to a mask plate on which the light transmittances at different positions are inconsistent. For example, if a light transmittance at a full tone position is 0%, for the positive photoresist material, a photoresist material will remain below the full tone position; a transmittance T at the half-tone position is 0%<T<100%. The transmittance of a corresponding halftone position may be determined according to a film thickness height of the halftone position. In this process, the photoresist here is of a halftone type, and since it is applied to a printing substrate, the photoresist may also have the property of a lyophobic surface. The specific process steps of the photoresist comprise: photoresist application→pre-baking→exposure→development→post-baking→UV (Ultra Violet) irradiation.

For example, a line bank substrate may be formed by single exposure with a halftone mask through the line bank process, and an upper-layer black matrix may be manufactured on an upper-layer cover plate, and then a QD (Quantum Dot) conversion layer structure may be formed in an attached manner.

In some embodiments, the plurality of sub-pixel groups comprise: a red sub-pixel group, a blue sub-pixel group and a green sub-pixel group, wherein an area of a red sub-pixel in the red sub-pixel group, an area of a blue sub-pixel in the blue sub-pixel group and an area of a green sub-pixel in the green sub-pixel group are all equal. The same pixel area can effectively improve the printing efficiency, and the setting of the printing template can be greatly simplified, so as to simplify the printing procedure, improve the printing efficiency, and optimize the pixel arrangement. Here, the printing efficiency of sub-pixels with different colors may be adjusted by different film thicknesses.

In other embodiments, the plurality of sub-pixel groups comprise: a red sub-pixel group, a blue sub-pixel group and a green sub-pixel group, wherein an area of a blue sub-pixel in the blue sub-pixel group is greater than an area of a red sub-pixel in the red sub-pixel group, and the area of the blue sub-pixel in the blue sub-pixel group is greater than an area of a green sub-pixel in the green sub-pixel group. The area of the red sub-pixel in the red sub-pixel group and the area of the green sub-pixel in the green sub-pixel group may or may not be equal. In the embodiment, a short service life of the blue sub-pixel can be compensated by increasing the area of the blue sub-pixel, thereby improving the overall service life of the display substrate.

In the embodiment of the present disclosure, by improving the pixel defining layer (that is, the first bank layer and the second bank layer), it is more suitable for manufacturing an organic light-emitting device by inkjet printing. In the manufacturing process, the above-described design may improve the film-forming uniformity of ink diffusion in pixels, and may improve the landing accuracy of ink droplets.

The arrangement of sub-pixels with the shape of each sub-pixel as a parallelogram has been described above. Of course, the scope of the present disclosure is not limited thereto. The display substrate in the embodiment of the present disclosure may also use other sub-pixel shapes, and the shapes of sub-pixels in other embodiments will be described in detail below in conjunction with the accompanying drawings.

FIG. 5 is a top view showing a display substrate according to another embodiment of the present disclosure.

In the display substrate shown in FIG. 5, a shape of each sub-pixel 220 is a rhombic shape. FIG. 5 shows a first bank layer 211 and a second bank layer 212. The second bank layer 212 comprises a third line portion 303 and a fourth line portion 304 adjacent to the third line portion 303. For example, as shown in FIG. 5, each sub-pixel group comprises a first sub-pixel 221, a second sub-pixel 222, and a third sub-pixel 223. As shown in FIG. 5, the first sub-pixel 221 is in a different sub-pixel row from the second sub-pixel 222, the second sub-pixel 222 is in a different sub-pixel row from the third sub-pixel 223, and a sub-pixel row 522 where the second sub-pixel 222 is located is between a sub-pixel row 521 where the first sub-pixel 221 is located and a sub-pixel row 523 where the third sub-pixel 223 is located.

In the display substrate of the embodiment, rhombic sub-pixels are formed into a sub-pixel group by using the above-described arrangement, which is beneficial to improve the light-emitting uniformity and pixel opening ratio of the sub-pixels, and to improve the resolution of the display substrate.

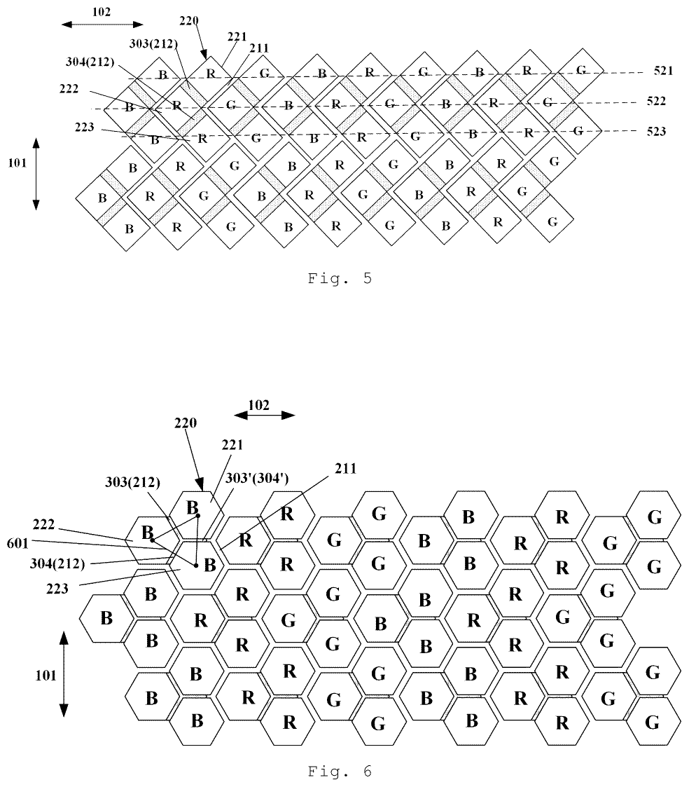

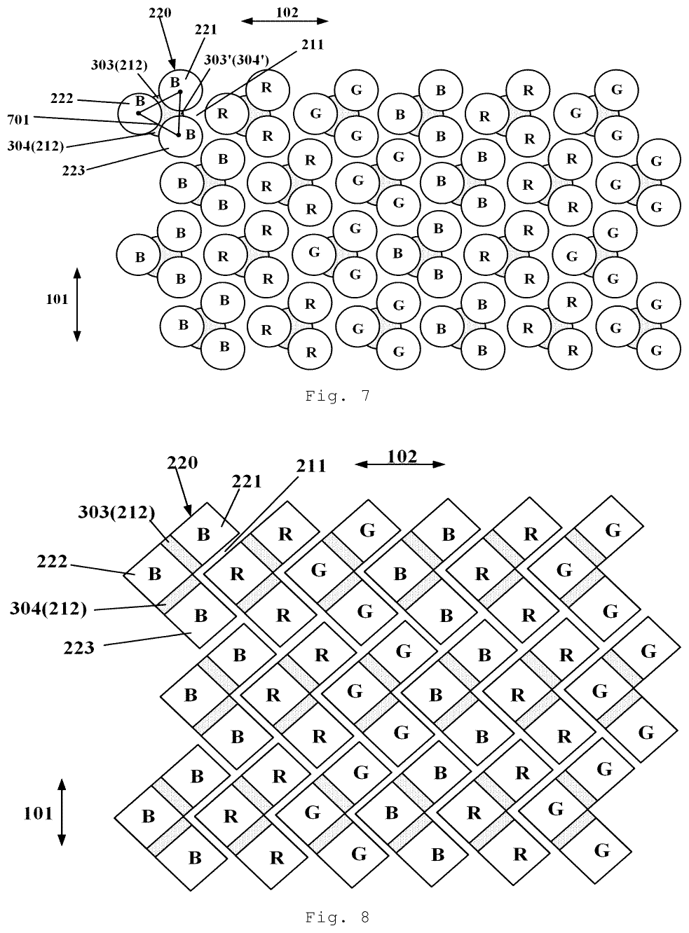

FIG. 6 is a top view showing a display substrate according to another embodiment of the present disclosure.

In the display substrate shown in FIG. 6, a shape of each sub-pixel 220 is a hexagonal shape (for example, regular hexagon). FIG. 6 shows a first bank layer 211 and a second bank layer 212. The second bank layer 212 comprises a third line portion 303 and a fourth line portion 304 adjacent to the third line portion 303. For example, as shown in FIG. 6, each sub-pixel group comprises a first sub-pixel 221, a second sub-pixel 222, and a third sub-pixel 223. In each sub-pixel group, a center of the first sub-pixel 221, a center of the second sub-pixel 222 and a center of the third sub-pixel 223 are at different vertices of an equilateral triangle 601 respectively. In other words, connecting lines of the center of the first sub-pixel 221, the center of the second sub-pixel 222 and the center of the third sub-pixel 223 are formed into an equilateral triangle 601. The first sub-pixel 221 and the third sub-pixel 223 are separated by another third line portion 303′ or another fourth line portion 304′. That is, an opening of the first sub-pixel 221, an opening of the second sub-pixel 222 and an opening of the third sub-pixel 223 are separated by the third line portion 303, the fourth line portion 304 and another line portion (which may be regarded as another third line portion or another fourth line portion) 303′ or 304′.

In the display substrate of the embodiment, hexagonal sub-pixels are formed into a sub-pixel group by using the above-described arrangement (which may be referred to as a honeycomb arrangement), which is beneficial to improve the light-emitting uniformity and pixel opening ratio of the sub-pixels, and to improve the resolution of the display substrate.

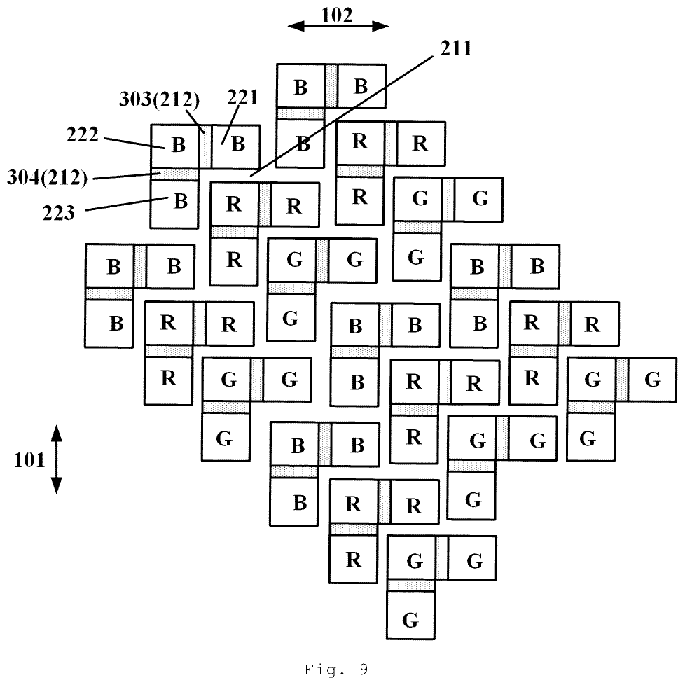

FIG. 7 is a top view showing a display substrate according to another embodiment of the present disclosure.

The arrangement of sub-pixels in FIG. 7 is similar to the arrangement of sub-pixels in FIG. 6. Different from the display substrate shown in FIG. 6, in the display substrate shown in FIG. 7, a shape of the sub-pixel is a circular shape.

That is, in the display substrate shown in FIG. 7, the shape of each sub-pixel 220 is a circular shape. FIG. 7 shows a first bank layer 211 and a second bank layer 212. The second bank layer 212 comprises a third line portion 303 and a fourth line portion 304 adjacent to the third line portion 303. For example, as shown in FIG. 7, each sub-pixel group comprises a first sub-pixel 221, a second sub-pixel 222, and a third sub-pixel 223. In each sub-pixel group, a center of the first sub-pixel 221, a center of the second sub-pixel 222 and a center of the third sub-pixel 223 are at different vertices of an equilateral triangle 701. In other words, connecting lines of the center of the first sub-pixel 221, the center of the second sub-pixel 222 and the center of the third sub-pixel 223 are formed into an equilateral triangle 701. The first sub-pixel 221 and the third sub-pixel 223 are separated by another third line portion 303′ or another fourth line portion 304′. That is, an opening of the first sub-pixel 221, an opening of the second sub-pixel 222 and an opening of the third sub-pixel 223 are separated by the third line portion 303, the fourth line portion 304 and another line portion (which may be regarded as another third line portion or another fourth line portion) 303′ or 304′.

In the display substrate of the embodiment, circular sub-pixels are: formed into a sub-pixel group by using the above-described arrangement (which may be referred to as quincunx array arrangement), which is beneficial to improve the light-emitting uniformity and pixel opening ratio of the sub-pixels, and to improve the resolution of the display substrate.

FIG. 8 is a top view showing a display substrate according to another embodiment of the present disclosure.

In the display substrate shown in FIG. 8, a shape of each sub-pixel 220 is a square shape. The square shape may be regarded as a special rhombic shape, and accordingly, the arrangement of sub-pixels shown in FIG. 8 is similar to the arrangement of sub-pixels shown in FIG. 5. FIG. 8 shows a first bank layer 211 and a second bank layer 212. The second bank layer 212 comprises a third line portion 303 and a fourth line portion 304 adjacent to the third line portion 303. For example, as shown in FIG. 8, each sub-pixel group comprises a first sub-pixel 221, a second sub-pixel 222, and a third sub-pixel 223. As shown in FIG. 8, the first sub-pixel 221 is in a different sub-pixel row from the second sub-pixel 222, the second sub-pixel 222 is in a different sub-pixel row from the third sub-pixel 223, and a sub-pixel row where the second sub-pixel 222 is located is between a sub-pixel row where the first sub-pixel 221 is located and a sub-pixel row where the third sub-pixel 223 is located.

In the display substrate of the embodiment, square sub-pixels are formed into a sub-pixel group by using the above-described arrangement, which is beneficial to improve the light-emitting uniformity and pixel opening ratio of the sub-pixels, and to improve the resolution of the display substrate.

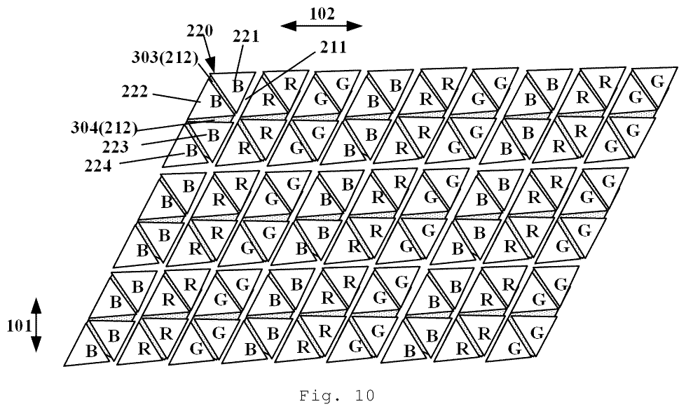

FIG. 9 is a top view showing a display substrate according to another embodiment of the present disclosure.

In the display substrate shown in FIG. 9, a shape of each sub-pixel 220 is a square shape. FIG. 9 shows another arrangement of square sub-pixels. For example, as shown in FIG. 9, each sub-pixel group comprises a first sub-pixel 221, a second sub-pixel 222, and a third sub-pixel 223. As shown in FIG. 9, the first sub-pixel 221 is in a same sub-pixel row as the second sub-pixel 222, and the second sub-pixel 222 is in a different sub-pixel row from the third sub-pixel 223. FIG. 9 shows a first bank layer 211 and a second bank layer 212. The second bank layer 212 comprises a third line portion 303 and a fourth line portion 304 adjacent to the third line portion 303. As shown in FIG. 9, a length of the third line portion 303 along the first direction 101 and a length of the fourth line portion 304 along the second direction 102 are both equal to a side length of each square sub-pixel 220.

In the display substrate of the embodiment, FIG. 9 shows another arrangement of square sub-pixels. Square sub-pixels are formed into a sub-pixel group by using the arrangement, which is beneficial to improve the light-emitting uniformity and pixel opening ratio of the sub-pixels, and to improve the resolution of the display substrate.

FIG. 10 is a top view showing a display substrate according to another embodiment of the present disclosure.

In the display substrate shown in FIG. 10, a shape of each sub-pixel 220 is a triangle shape (for example, a equilateral triangle). FIG. 10 shows a first bank layer 211 and a second bank layer 212. The second bank layer 212 comprises a third line portion 303 and a fourth line portion 304 adjacent to the third line portion 303. For example, as shown in FIG. 10, each sub-pixel group comprises a first sub-pixel 221, a second sub-pixel 222, and a third sub-pixel 223. As shown in FIG. 10, the first sub-pixel 221 is in a different sub-pixel row from the second sub-pixel 222, the second sub-pixel 222 is in a different sub-pixel row from the third sub-pixel 223, and a sub-pixel row where the second sub-pixel 222 is located is between a sub-pixel row where the first sub-pixel 221 is located and a sub-pixel row where the third sub-pixel 223 is located.

In some embodiments, as shown in FIG. 10, each sub-pixel group further comprises a fourth sub-pixel 224. A sub-pixel row where the fourth sub-pixel 224 is located is on a side of the sub-pixel row where the third sub-pixel 223 is located away from the sub-pixel row where the second sub-pixel 222 is located. In other words, the sub-pixel row where the third sub-pixel 223 is located is between the sub-pixel row where the second sub-pixel 222 is located and the sub-pixel row where the fourth sub-pixel 224 is located.

In the display substrate of the embodiment, triangular sub-pixels are formed into a sub-pixel group by using the above-described arrangement, which is beneficial to improve the light-emitting uniformity and pixel opening ratio of the sub-pixels, and to improve the resolution of the display substrate.

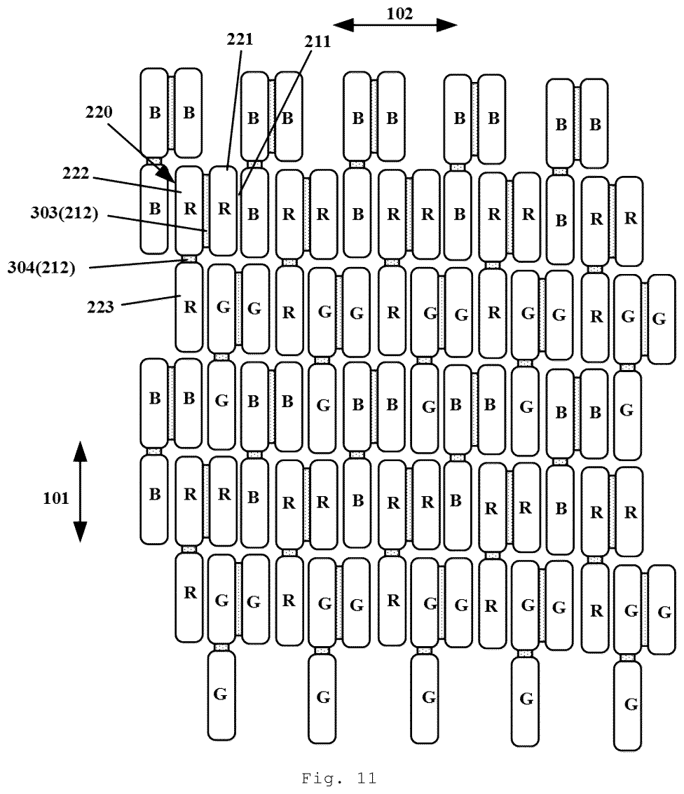

FIG. 11 is a top view showing a display substrate according to another embodiment of the present disclosure.

As shown in FIG. 11, a shape of each sub-pixel 220 is a long strip shape with rounded corners. Each sub-pixel group comprises a first sub-pixel 221, a second sub-pixel 222, and a third sub-pixel 223. The first sub-pixel 221 is in a same sub-pixel row as the second sub-pixel 222, and the second sub-pixel 222 is in a different sub-pixel row from the third sub-pixel 223. FIG. 11 shows a first bank layer 211 and a second bank layer 212. The second bank layer 212 comprises a third line portion 303 and a fourth line portion 304 adjacent to the third line portion 303. As shown in FIG. 11, a length of the third line portion 303 along the first direction 101 is less than a length of the second sub-pixel 222 along the first direction 101, and a length of the fourth line portion 304 along the second direction 102 is less than a length of the second sub-pixel 222 along the second direction 102. In other words, the third line portion 303 retracts inward relative to the second sub-pixel 222, and the fourth line portion 304 retracts inward relative to the second sub-pixel 222. This design is beneficial to improve the resolution of the display substrate, and to improve the light-emitting uniformity and pixel opening ratio of the sub-pixels.

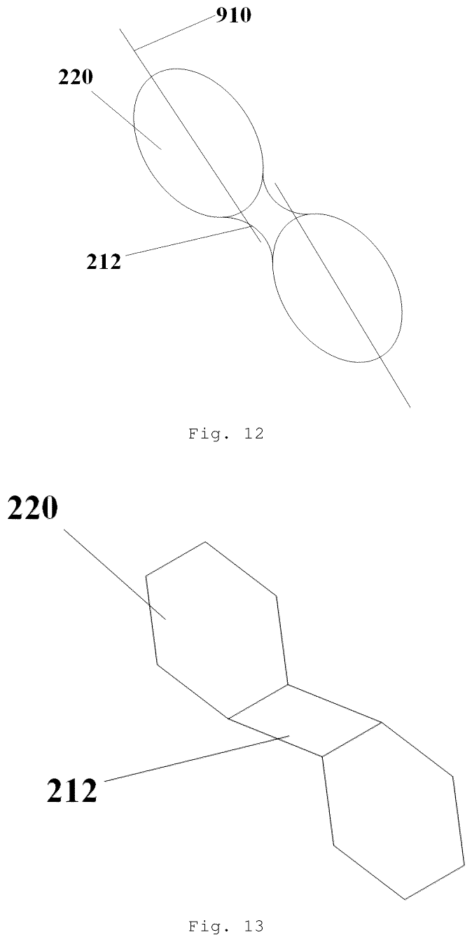

FIG. 12 is a schematic view showing an elliptical sub-pixel according to an embodiment of the present disclosure. As shown in FIG. 12, a shape of the sub-pixel 220 is an ellipse shape. In other embodiments, the shape of the sub-pixel 220 may also be a half of an ellipse shape, for example, a half of the ellipse shape taken by a median line 910 in FIG. 12.

FIG. 13 is a schematic view showing a hexagonal sub-pixel according to an embodiment of the present disclosure. A shape of the sub-pixel shown in FIG. 13 is also a hexagonal shape, but the hexagonal shape is not a regular hexagon.

It is to be noted that, the shape of the sub-pixel in each embodiment described above is only exemplary. In fact, the shape of the sub-pixel may also be another shape. For example, the shape of the sub-pixel may also be an octagonal shape. Therefore, the scope of the present disclosure is not limited thereto.

In some embodiments of the present disclosure, in the display substrate, all the sub-pixels may be in a parallel and center-aligned state, which facilitates controlling the frequency and algorithm of the printer during the implementation of the inkjet printing process.

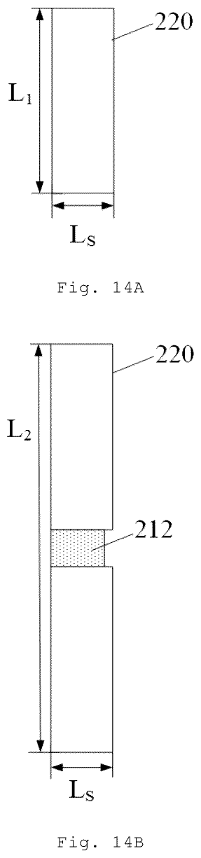

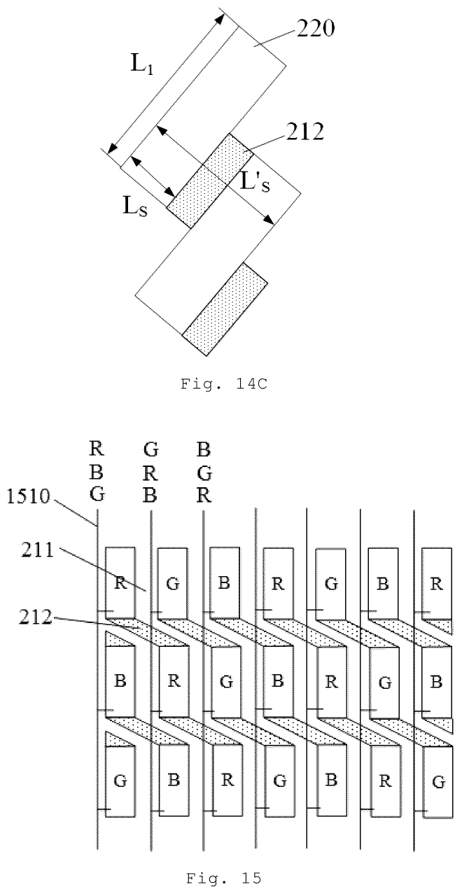

FIG. 14A is a schematic view showing calculation of an area of a sub-pixel according to an embodiment of the present disclosure.

FIG. 14A shows a length L₁ of the sub-pixel 220 along a long axis direction and a length L_{S} of the sub-pixel 220 along a short axis direction. An area uniformity of the sub-pixel=U(L₁)*U(L_{S}), where U(L₁) represents a uniformity value of the sub-pixel along the long axis direction, and the uniformity value U (L₁) is a percentage of a length of a portion with uniform light emission along the long axis direction to the length L₁ of the sub-pixel along the long axis direction, and the uniformity value is measured by a white light interferometer or other devices; and U (L_{S}) represents a uniformity value of the sub-pixel along the short axis direction, and the uniformity value U(L_{S}) is a percentage of a length of the portion with uniform light emission along the short axis direction of the sub-pixel to the length L_{S} of the sub-pixel along the short axis direction, and the uniformity value is measured by the white light interferometer or other devices. The area uniformity is a percentage value. The area uniformity also reflects a film thickness uniformity in a certain area (especially in an area of a light emitting pixel).

FIG. 14B is a schematic view showing calculation of an area of a sub-pixel with long axis connection according to an embodiment of the present disclosure.

As shown in FIG. 14B, long axis directions of two sub-pixels 220 are on a same straight line (similar to the structure of two adjacent sub-pixels shown in FIG. 1), which may be referred to as long axis connection, and there is a second bank layer 212 between the two sub-pixels 220. FIG. 14B shows a length L₂ of two sub-pixels 220 along a long axis direction and a length L_{S} of the two sub-pixels 220 along a short axis direction. An area uniformity of the two sub-pixels=U(L₂)*U(L_{S}), where U (L₂) represents a uniformity value of a structure of the long axis connection of the two sub-pixels along the long axis direction, and the uniformity value U (L₂) is a percentage of a length of a portion of the sub-pixels with uniform light emission along the long axis direction in the structure of the long axis connection of the two sub-pixels to a length L₂ of a structure of the two sub-pixels along the long axis direction, and the uniformity value is measured by a white light interferometer or other devices; and U(L_{S}) represents a uniformity value of the structure of the long axis connection of the two sub-pixels along the short axis direction, and the uniformity value U (L_{S}) is a percentage of a length of a portion of the sub-pixels with uniform light emission along the short axis direction in the structure of the long axis connection of the two sub-pixels to the length L_{S} of the structure of the long axis connection of the two sub-pixels along the short axis direction, and the uniformity value is measured by the white light interferometer or other devices.

FIG. 14C is a schematic view showing calculation of an area of a sub-pixel connected in a staggered manner according to another embodiment of the present disclosure.

As shown in FIG. 14C, long axis directions of the two sub-pixels 220 are parallel, the two sub-pixels 220 are arranged in a staggered manner, and the second bank layer 212 is between the two sub-pixels 220. FIG. 14C shows a length L₁ of the sub-pixel 220 along a long axis direction and a length L_{S} of the sub-pixel 220 along a short axis direction, and also shows a length L'_{S} of the two sub-pixels side by side along a short axis direction. An area uniformity of two adjacent sub-pixels=U(L₁)*U(L'_{S})≈U(L₁)*U(L₁), where U(L₁) represents a uniformity value of a connection structure of two sub-pixels arranged in a staggered manner along the long axis direction, the uniformity value U(L₁) is a percentage of a length of a portion of the sub-pixels with uniform light emission along the long axis direction in the connection structure of the two sub-pixels arranged in a staggered manner to the length L₁ of the connection structure of the two sub-pixels arranged in a staggered manner along the long axis direction, and the uniformity value is measured by a white light interferometer or other devices; and U(L's) represents a uniformity value of the connection structure of two sub-pixels arranged in a staggered manner along the short axis direction, the uniformity value U(L'_{S}) is a percentage of a length of a portion of the sub-pixels with uniform light emission along the short axis direction in the connection structure of the two sub-pixels arranged in a staggered manner to the length L'_{S} of the connection structure of the two sub-pixels arranged in a staggered manner along the short axis direction, and the uniformity value is measured by the white light interferometer or other devices. Here, a short axis portion in the middle that is actually not connected is not considered when an area is calculated.

In addition, Table 1 shows the area uniformity of the display substrate in a case where the long axis of the sub-pixel is not connected, the short axis of the sub-pixel is not connected, the long axis of the sub-pixel is connected, and the short axis of the sub-pixel is connected, and so on.

As can be seen from Table 1, for a sub-pixel structure (for example, a single sub-pixel or sub-pixel group), the uniformity in the long axis direction is greater than the uniformity in the short axis direction.

In addition, as can also be seen from Table 1, with the increase of PPI of the display substrate, the proportion of the uniformity of the area of the short axis connection in the uniformity of the overall area gradually increases, also that is, the influence of short axis connection gradually increases.

Furthermore, as can also be seen from Table 1, with the increase of printing thickness (that is, the film thickness) (that is, quantity of the printing ink is increased), the influence on the uniformity of the area gradually increases, so that the connection also functions more significantly.

TABLE 1

| | | Area | PPI | | | | | | | | |
|---|---|---|---|---|---|---|---|---|---|---|---|
| | | uniformity | 160 | 200 | 255 | 160 | 200 | 255 | 160 | 200 | 255 |
| Sub-pixel | Not | Long | 78.0% | 73.0% | 70.0% | 78.0% | 73.0% | 70.0% | 78.0% | 73.0% | 70.0% |
| structure | connection | axis | | | | | | | | | |
| | | Short | 70.0% | 66.0% | 60.0% | 65.0% | 60.0% | 55.0% | 60.0% | 55.0% | 50.0% |
| | | axis | | | | | | | | | |
| | After | Long | 90.0% | 89.0% | 88.0% | 90.0% | 89.0% | 88.0% | 90.0% | 89.0% | 88.0% |
| | connection | axis | | | | | | | | | |
| | | Short | 78.0% | 73.0% | 70.0% | 78.0% | 73.0% | 70.0% | 78.0% | 73.0% | 70.0% |
| | | axis | | | | | | | | | |

| | | Area uniformity | | | Area uniformity | | | Area uniformity | | |
|---|---|---|---|---|---|---|---|---|---|---|
| | | (small film thickness) | | | (medium film thickness) | | | (large film thickness) | | |
| | | | Long | Short | | Long | Short | | Long | Short |
| | | Not | axis | axis | Not | axis | axis | Not | axis | axis |
| | PPI | connected | connected | connected | connected | connected | connected | connected | connected | connected |
| Display | 160 (actually | 54.6% | 63.0% | 60.8% | 50.7% | 58.5% | 60.8% | 46.8% | 54.0% | 60.8% |
| substrate | produced) | | | | | | | | | |
| | 200 (actually | 48.2% | 58.7% | 53.3% | 43.8% | 53.4% | 53.3% | 40.2% | 49.0% | 53.3% |
| | produced) | | | | | | | | | |
| | 255 (actually | 42.0% | 52.8% | 49.0% | 38.5% | 48.4% | 49.0% | 35.0% | 44.0% | 49.0% |
| | produced) | | | | | | | | | |
| | 295 (expected) | 38.7% | 50.1% | 45.3% | | | | | | |

In some embodiments of the present disclosure, a display device is also provided. The display device comprises the display substrate as described previously. For example, the display device is any product or member having a display function, such as a display panel, a mobile phone, a tablet computer, a television, a display, a notebook computer, a digital photo frame, a navigator, or the like.

Hereto, various embodiments of the present disclosure have been described in detail. Some details well known in the art are not described in order to avoid obscuring the concept of the present disclosure. According to the above description, those skilled in the art would fully understand how to implement the technical solutions disclosed here.

Although some specific embodiments of the present disclosure have been described in detail by way of examples, those skilled in the art should understand that the above examples are only for an illustrative purpose, rather than limiting the scope of the present disclosure. It should be understood by those skilled in the art that modifications to the above embodiments and equivalent replacements to some technical features may be made without departing from the scope and spirit of the present disclosure. The scope of the present disclosure is defined by the appended claims.

1. A display substrate, comprising:
a base substrate; and
a plurality of sub-pixel groups on the base substrate, wherein sub-pixels in each sub-pixel group of the plurality of sub-pixel groups have a same light-emitting color, and sub-pixel groups with different colors are separated by a first bank layer, wherein:
the each sub-pixel group comprises a plurality of sub-pixels, wherein adjacent sub-pixels of the plurality of sub-pixels are separated by a second bank layer, a height of the second bank layer in a direction perpendicular to the base substrate is less than a height of the first bank layer in the direction perpendicular to the base substrate, the second bank layer is adjacent to the first bank layer, and in the each sub-pixel group, an extension line of a midpoint of the second bank layer between two adjacent sub-pixels of the plurality of sub-pixels in a first direction is not coincident with at least one of extension lines of respective midpoints of the two adjacent sub-pixels in the first direction.

2. The display substrate according to claim 1, wherein a width of at least one sub-pixel of the plurality of sub-pixels in a second direction is greater than a width of the second bank layer in the second direction, wherein the second direction intersects with the first direction.

3. The display substrate according to claim 1, wherein the extension line of the midpoint of the second bank layer between the two adjacent sub-pixels of the plurality of sub-pixels in the first direction is between the extension lines of the respective midpoints of the two adjacent sub-pixels in the first direction, wherein the second direction intersects with the first direction.

4. (canceled)

5. The display substrate according to claim 2, wherein the first direction is a column direction of a sub-pixel array comprising the plurality of sub-pixel groups, and the second direction is a row direction of a sub-pixel array comprising the plurality of sub-pixel groups.

6. The display substrate according to claim 1, wherein an extension shape of the first bank layer is a broken line shape or a wavy line shape.

7. The display substrate according to claim 1, wherein the display substrate comprises a plurality of first bank layers, wherein extension directions of at least two first bank layers of the plurality of first bank layers are substantially parallel, and lengths of the at least two first bank layers are equal.

8. The display substrate according to claim 1, wherein the first bank layer comprises a first line portion and a second line portion wherein the first line portion and the second line portion are alternately distributed and connected as a whole, extension directions of different first line portions in the first bank layer are parallel, and extension directions of different second line portions in the first bank layer are parallel.

9. The display substrate according to claim 8, wherein:
the second line portion extends along the second direction, and
the first line portion and the second line portion form a first angle, wherein the first angle is not 90 degrees; and/or
a width of the first line portion in the second direction is equal to a width of the second line portion in the first direction.

10. (canceled)

11. (canceled)

12. The display substrate according to claim 3, wherein the second bank layer comprises a third line portion and a fourth line portion, wherein the third line portion and the fourth line portion are alternately distributed, and extension directions of different third line portions in the second bank layer are parallel, and extension directions of different fourth line portions in the second bank layer are parallel.

13. The display substrate according to claim 12, wherein:
the fourth line portion extends along the second direction; and
the third line portion and the fourth line portion form a second angle, wherein the second angle is not 90 degrees; and/or
a width of the third line portion in the second direction is equal to a width of the fourth line portion first direction.

14. (canceled)

15. (canceled)

16. The display substrate according to claim 1, wherein a width of the first bank layer in a direction perpendicular to an extension direction of the first bank layer is equal to a width of the second bank layer in a direction perpendicular to an extension direction of the second bank layer.

17. The display substrate according to claim 1, wherein:
the height of the first bank layer ranges from 1.2 microns to 1.8 microns, and
the height of the second bank layer ranges from 0.5 micron to 1 micron; and/or
a material of the first bank layer is the same as a material of the second bank layer, and the first bank layer and the second bank layer are connected as a whole.

18. (canceled)

19. The display substrate according to claim 1, wherein the plurality of sub-pixel groups comprise a red sub-pixel group, a blue sub-pixel group and a green sub-pixel group, wherein an area of a red sub-pixel in the red sub-pixel group, an area of a blue sub-pixel in the blue sub-pixel group and an area of a green sub-pixel in the green sub-pixel group are all equal.

20. The display substrate according to claim 1, wherein the plurality of sub-pixel groups comprise a red sub-pixel group, a blue sub-pixel group and a green sub-pixel group, wherein an area of a blue sub-pixel in the blue sub-pixel group is greater than an area of a red sub-pixel in the red sub-pixel group, and the area of the blue sub-pixel in the blue sub-pixel group is greater than an area of a green sub-pixel in the green sub-pixel group.

21. The display substrate according to claim 1, wherein:
the second bank layer comprises a third line portion and a fourth line portion adjacent to the third line portion; and
the each sub-pixel group comprises at least three sub-pixels, wherein the at least three sub-pixels comprises a first sub-pixel, a second sub-pixel adjacent to the first sub-pixel and a third sub-pixel adjacent to the second sub-pixel, wherein the first sub-pixel and the second sub-pixel are separated by the third line portion, and the second sub-pixel and the third sub-pixel are separated by the fourth line portion.

22. The display substrate according to claim 21, wherein:
a shape of each of the plurality of sub-pixels is a parallelogram shape or an ellipse shape; and
the first sub-pixel is in a same sub-pixel row as the second sub-pixel, and the second sub-pixel is in a different sub-pixel row from the third sub-pixel.

23. The display substrate according to claim 22, wherein the at least three sub-pixels comprise a plurality of sub-pixel rows, wherein each of the plurality of sub-pixel rows comprises at least two sub-pixels, and in the each sub-pixel group, the at least two sub-pixels in different sub-pixel rows are arranged in a staggered manner.

24. The display substrate according to claim 21, wherein:
a shape of each of the plurality of sub-pixels is a rhombic shape or a triangle shape; and
the first sub-pixel is in a different sub-pixel row from the second sub-pixel, the second sub-pixel is in a different sub-pixel row from the third sub-pixel, and a sub-pixel row where the second sub-pixel is located is between a sub-pixel row where the first sub-pixel is located and a sub-pixel row where the third sub-pixel is located.

25. The display substrate according to claim 21, wherein:
a shape of each of the plurality of sub-pixels is a hexagonal shape or a circular shape;
in the each sub-pixel group, a center of the first sub-pixel, a center of the second sub-pixel and a center of the third sub-pixel are at different vertices of an equilateral triangle; and
the first sub-pixel and the third sub-pixel are separated by another third line portion or another fourth line portion.

26. A display device, comprising: the display substrate according to claim 1.
